(19) United States
(12) Patent Application Publication
(10) Pub. No.: US 2016/0104402 A1
(43) Pub. Date: Apr. 14, 2016

(54) ORGANIC LIGHT-EMITTING DISPLAY PANEL AND TEST METHOD

(71) Applicant: Samsung Display Co., Ltd., Yongin-city (KR)

(72) Inventor: Jihye KIM, Yongin-city (KR)

(21) Appl. No.: 14/698,292

(22) Filed: Apr. 28, 2015

(30) Foreign Application Priority Data
Oct. 13, 2014 (KR) 10-2014-0137853

(51) Int. Cl. G09G 3/00; G01R 31/26

(52) U.S. Cl. CPC G09G 3/006; G01R 31/2635

(57) ABSTRACT

An organic light-emitting display panel includes a pixel unit including a plurality of pixels configured to display different colors, wherein the plurality of pixels is respectively disposed at intersections of a plurality of scan lines and a plurality of data lines; and a test unit configured to selectively apply, to a plurality of link lines connected to the data lines, a pixel test signal for detecting defects of the plurality of pixels and a link line test signal for detecting short and open states of the plurality of link lines.

### CROSS REFERENCE TO RELATED APPLICATION

This application claims priority from and the benefit of Korean Patent Application No. 10-2014-0137853, filed on Oct. 13, 2014, which is hereby incorporated by reference for all purposes as if fully set forth herein.

### BACKGROUND

1. Field

Exemplary embodiments relate to an organic light-emitting display panel and a method of testing the same.

2. Discussion of the Background

An organic light-emitting display apparatus displays images by using self-emitting devices such as organic light-emitting devices (OLEDs).

According to the related art, an organic light-emitting display apparatus may be manufactured by forming a large scale integration (LSI) circuit, in which driver circuits for generating and applying scan signals and data signals to pixels are integrated, and connecting the LSI circuit to a pixel array substrate, on which the pixels are arranged in an array, by using a tape automated bonding (TAB) method. An organic light-emitting display apparatus in which the driver circuit and the pixel array substrate are connected using the TAB method requires a plurality of leads to connect the pixel array substrate and the driver circuit. Such configuration, however, may cause difficulty in manufacturing the organic light-emitting display apparatus and decreased reliability and a yield rate thereof. Also, the expensive price of the LSI circuit may have increased the organic light-emitting display apparatus price.

In order to solve the problems above, a chip-on-glass (COG) organic light-emitting display apparatus or a system on panel (SOP) organic light-emitting display apparatus, which are manufactured by directly integrating a driver circuit to a pixel circuit array substrate on which pixel circuits are disposed, may be used. The COG or SOP organic light-emitting display apparatuses may be manufactured without a separate process of connecting the driver circuit and the pixel circuit array substrate, and thus enhanced reliability and a yield rate.

The above information disclosed in this Background section is only for enhancement of understanding of the background of the invention and therefore it may contain information that does not form any part of the prior art nor what the prior art may suggest to a person of ordinary skill in the art.

### SUMMARY

Exemplary embodiments include a display panel configured to perform a panel test. This may reduce a dead space within the display panel by including a single test circuit.

Additional aspects will be set forth in part in the description which follows, and in part will be apparent from the description, or may be learned by practice of the presented exemplary embodiments.

An exemplary embodiment discloses an organic light-emitting display panel including: a pixel unit including a plurality of pixels configured to display different colors, wherein the plurality of pixels is respectively disposed at intersections of a plurality of scan lines and a plurality of data lines; and a test unit is configured to selectively apply, to a plurality of link lines connected to the data lines, a pixel test signal for detecting defects of the plurality of pixels and a link line test signal for detecting short and open states of the plurality of link lines.

An exemplary embodiment discloses a method of testing an organic light-emitting display panel including: applying a pixel test signal, for detecting a lighting defect of a plurality of pixels, to a plurality of link lines respectively connected to a plurality of data lines; and applying a link line test signal, for detecting short and open states of the plurality of link lines, to the plurality of link lines.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a flowchart of a method of manufacturing an organic light-emitting display apparatus, according to an exemplary embodiment.

FIG. 2 is a schematic plan view of an organic light-emitting display panel according to an exemplary embodiment.

FIG. 3 is a plan view of an example of the organic light-emitting display panel of FIG. 2.

FIG. 4 is a timing diagram for describing a lighting test of the organic light-emitting display panel of FIG. 3.

FIG. 5 is a timing diagram for describing a link line test of the organic light-emitting display panel of FIG. 3.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements. Like reference numerals in the drawings denote like elements, and thus their description will be omitted.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

It will be understood that although the terms “first,” “second,” etc. may be used herein to describe various components, these components should not be limited by these terms. These components are only used to distinguish one component from another.

As used herein, the singular forms “a,” “an” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

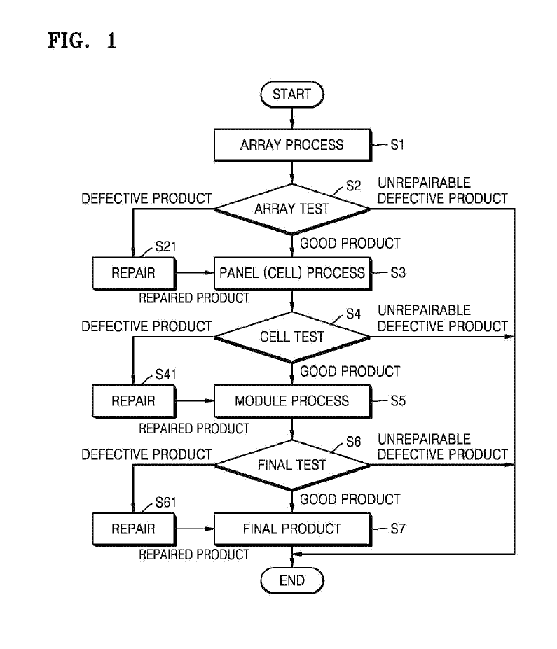

FIG. 1 is a flowchart of a method of manufacturing an organic light-emitting display apparatus according to an exemplary embodiment.

First, an array process (S1) may be performed to form a pixel circuit array on a substrate. Each pixel circuit may include at least two thin film transistors (TFTs) and at least one capacitor. Next, the array may be tested to detect whether the pixel circuit has defects. During the array test (S2), the TFTs may be tested to determine whether they operate normally. If a pixel circuit is determined as defective after the array test (S2), it may proceed to a repair process (S21). However, if the pixel circuit is determined as a defective product that is not repairable, it proceeds to end.

A pixel circuit array determined good or repaired may proceed to a panel (cell) process (S3). During the panel (cell) process (S3), an anode electrode, an organic emission layer, and a cathode electrode may be disposed to manufacture an organic light-emitting device (OLED). Then, the cells are tested. The cell test (S4) may include a lighting test, a link line test, a leakage current test, and/or aging test with respect to a panel. If a panel is determined as defective in the cell test (S4), it may proceed to a repair process (S41). However, if the panel is determined as a defective product that is not repairable, it proceeds to end.

A panel that is determined good product or repaired may proceed to a module process (S5) and a final test (S6) to separate a final product and a defective product. If a module that is determined defective in the final test (S6), it may proceed to a repair process (S61). However, if the module is determined as a defective product that is not repairable, it proceeds to end. If the module is determined as a good product or a repaired product, the module is processed as a final product.

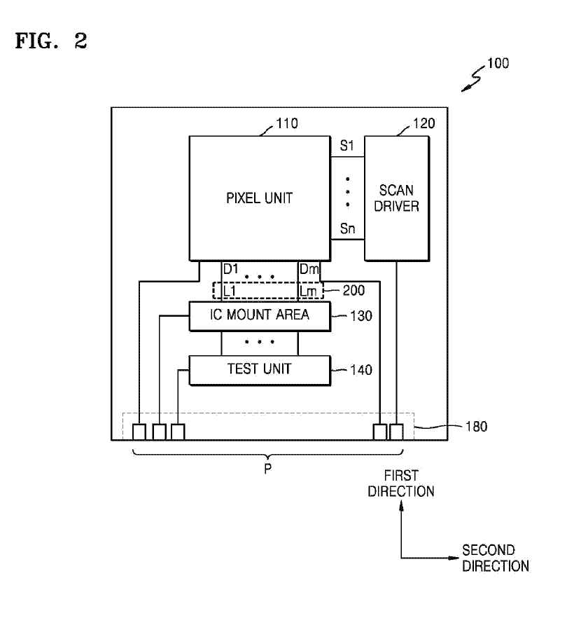

FIG. 2 is a schematic plan view of an organic light-emitting display panel 100 according to an exemplary embodiment.

Referring to FIG. 2, according to an embodiment organic light-emitting display panel 100 includes a pixel unit 110, a scan driver 120, an integrated circuit (IC) mount area 130, a test unit 140, and a pad unit 180.

The pixel unit 110 may include a plurality of pixels that are disposed at intersections of data lines D1 to Dm and scan lines S1 to Sn and are configured to emit different grayscales. The data lines D1 to Dm extend in a first direction and the scan lines S1 to Sn extend in a second direction.

The scan driver 120 generates a scan signal, in response to a scan driving power VDD and VSS and a scan control signal SCS, that are supplied from the outside, and sequentially supply the scan signal to the scan lines S1 to Sn.

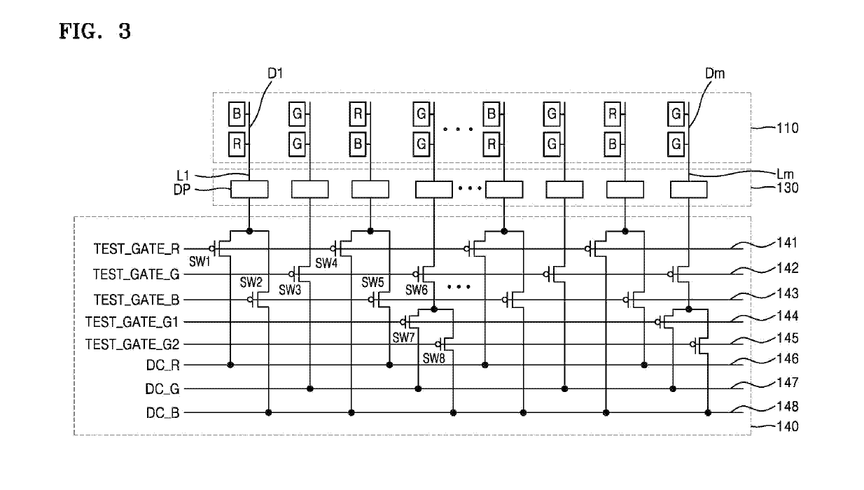

A plurality of data pads DP (referring to FIG. 3), wherein each of the plurality of data pads is respectively connected at each ends of the data lines D1 to Dm of the pixel unit 110, may be provided in the IC mount area 130. A data driver (not shown) may be bonded to the plurality of data pads by using a chip-on-glass (COG) method and mounted in the IC mount area 130. The data driver generates a data signal in response to data and a data control signal, and supplied the data signal to the data lines D1 to Dm.

The test unit 140 may selectively apply a pixel test signal and/or a link line test signal to link lines L1 to Lm disposed in a fanout unit 200. The link lines L1 to Lm are lines extending from the data lines D1 to Dm of the pixel unit 110 to the IC mount area 130. The pixel test signal and the link line test signal may be selectively applied to the data lines D1 to Dm via the link lines L1 to Lm.

Among the link lines L1 to Lm, odd number link lines (L1, L3, . . . , Lm−1) and even number link lines (L2, L4, . . . , Lm) may be disposed on different layers having at least one insulating layer disposed between the layers. For example, the odd number link lines (L1, L3, . . . , Lm−1) may be adjacently arranged in an array on a lower layer, the at least one insulating layer may be formed on the odd number link lines (L1, L3, . . . , Lm−1), and the even number link lines (L2, L4, . . . , Lm) may be adjacently arranged in an array on an upper layer of the at least one insulating layer. The even number link lines (L2, L4, . . . , Lm) may be arranged between the odd number link lines (L1, L3, . . . , Lm−1). In another example, the even number link lines (L2, L4, . . . , Lm) may be adjacently arranged in an array on a lower layer, the at least one insulating layer may be formed on the even number link lines (L2, L4, . . . , Lm), and the odd number link lines (L1, L3, . . . , Lm−1) may be adjacently arranged in an array on an upper layer of the at least one insulating layer.

The test unit 140 may perform a lighting test to test whether a pixel is defective. The test unit 140 may receive the pixel test signal and a control signal for the lighting test, and supply the pixel test signal to the link lines L1 to Lm in response to the control signal.

Also, the test unit 140 may perform a link line test to detect short and open states of the link lines L1 to Lm. The test unit 140 may receive the link line test signal and a control signal for the link line test, and supply the link line test signal to the link lines L1 to Lm in response to the control signal.

The pixel test signal and the link line test signal that are supplied to the link lines L1 to Lm are supplied to the data lines D1 to Dm.

The test unit 140 may selectively perform the lighting test and the link line test according to the control signal.

The pad unit 180 may include a plurality of pads P for supplying power and/or signals supplied from the outside into the organic light-emitting display panel 100. Respective positions and the number of lines connecting the pad unit 180 to elements of the organic light-emitting display panel 100 shown in FIG. 2 are illustrated for convenience of description, and are not limited thereto. For example, line that connected from the pad unit 180 to the scan driver 120 may be five lines that respectively receive the scan driving power VDD and VSS, a start pulse SP as the scan control signal SCS, a scan clock signal CLK, and an output enable signal OE.

The organic light-emitting display panel 100 according to an embodiment may further include an emission control unit (not shown) configured to apply an emission control signal to the pixel unit 110 so that sufficient amount of test signals may be applied to the plurality of pixels when executing the cell test (S4).

FIG. 3 is a plan view of an example of the organic light-emitting display panel 100 of FIG. 2. Referring to FIG. 3, a pixel unit 110 may include first pixels, second pixels, and third pixels that emit different colors. The pixel unit 110 may have a structure wherein the first pixels and the second pixels are alternately arranged in a single column, and the third pixels are arranged in another single column adjacent to the single column in which the first and second pixels are arranged.

The first pixels may be red pixels R configured to emit red light, the second pixels may be blue pixels B configured emit blue light, and the third pixels may be green pixels G configured to emit green light. The red pixels R and the blue pixels B may be alternately arranged in a single column, and the green pixels G may be arranged in another single column adjacent to the single column in which the red pixels R and the blue pixels B are arranged.

The red pixels R and the blue pixels B may be arranged in a checker board pattern, such that the red pixels R are disposed diagonal to each other and the blue pixels B are disposed diagonal to each other, with the column of the green pixels G arranged between each columns of the red pixels R and the blue pixels B. That is, each of the red pixels R and the blue pixels B, disposed in same row of two adjacent columns, may be alternately arranged such that the same pixels are not repeatedly disposed in the same column of two adjacent rows. The data lines D1 to Dm may be disposed in each column.

For example, the red pixels R and the blue pixels B may be alternately arranged in a first column, the green pixels G may be arranged in a second column, the red pixels R and the blue pixels B may be arranged in a third column in an order opposite to the order of the red pixels R and the blue pixels B of the first column, and the green pixels G may be arranged in a fourth column. The first to fourth columns may be repeatedly disposed in the pixel unit 110.

According to an embodiment, the pixel unit 110 includes the red pixels R, the blue pixels B, and the green pixels G, but the pixel unit 110 is not limited thereto. The pixel unit 110 may include pixels that display colors other than red, green, and blue.

The plurality of data pads DP is disposed in the IC mount area 130, wherein each of the plurality of data pads DP may be connected to the link lines L1 to Lm, wherein the link lines L1 to Lm extend from the data lines D1 to Dm.

The test unit 140 includes first to eighth test switches SW1 to SW8. Each of the first to eighth test switches SW1 to SW8 may include a gate connected to one of first to fifth control signal lines 141 to 145 configured to supply a test control signal, a first terminal connected to one of the link lines L1 to Lm, and a second terminal connected to one selected from first to third test signal lines 146 to 148 configured to supply the pixel test signal or the link line test signal.

For example, a gate of the first test switch SW1 may be connected to the first control signal line 141 configured to supply a first control signal TEST_GATE_R, a first terminal of the first test switch SW1 may be connected to one of data lines (D1, D5, . . . ) of the first column, and a second terminal of the first test switch SW1 may be connected to the first test signal line 146 configured to supply a first test signal DC_R. The first test signal DC_R may be a first pixel test signal or a first link line test signal.

A gate of the second test switch SW2 may be connected to the second control signal line 143 configured to supply a second control signal TEST_GATE_B, a first terminal of the second test switch SW2 may be connected to one of the data lines (D1, D5, . . . ) of the first column, and a second terminal of the second test switch SW2 may be connected to the second test signal line 148 configured to supply a second test signal DC_B. The second test signal DC_B may be a second pixel test signal or a second link line test signal.

A gate of the third test switch SW3 may be connected to the third control signal line 142 configured to supply a third control signal TEST_GATE_G, a first terminal of the third test switch SW3 may be connected to one of the data lines (D2, D6, . . . ) of the second column, and a second terminal of the third test switch SW3 may be connected to the third test signal line 147 configured to supply the third test signal DC_G. The third test signal DC_G may be a third pixel test signal or a third link line test signal.

A gate of the fourth test switch SW4 may be connected to the first control signal line 141 configured to supply the first control signal TEST_GATE_R, a first terminal of the fourth test switch SW4 may be connected to one of the data lines (D3, D7, . . . ) of the third column, and a second terminal of the fourth test switch SW4 may be connected to the second test signal line 148 configured to supply the second test signal DC_B.

A gate of the fifth test switch SW5 may be connected to the second control signal line 143 configured to supply the second control signal TEST_GATE_B, a first terminal of the fifth test switch SW5 may be connected to one of the data lines (D3, D7, . . . ) of the third column, and a second terminal of the fifth test switch SW5 may be connected to the first test signal line 146 configured to supply the first test signal DC_R.

A gate of the sixth test switch SW6 may be connected to the third control signal line 142 configured to supply the third control signal TEST_GATE_G, a first terminal of the sixth test switch SW6 may be connected to one of the data lines (D4, D8, . . . ) of the fourth column, and a second terminal of the sixth test switch SW6 may be connected to a first terminal of the seventh test switch SW7 and a first terminal of the eighth test switch SW8.

A gate of the seventh test switch SW7 may be connected to the fourth control signal line 144 configured to supply the fourth control signal TEST_GATE_G1, the first terminal of the seventh test switch SW7 may be connected to the second terminal of the sixth test switch SW6, and a second terminal of the seventh test switch SW7 may be connected to the third test signal line 147 configured to supply the third test signal DC_G. The seventh test switch SW7 may be turned on during the lighting test and turned off during the link line test.

A gate of the eighth test switch SW8 may be connected to the fifth control signal line 145 configured to supply the fifth control signal TEST_GATE_G2, the first terminal of the eighth test switch SW8 may be connected to the second terminal of the sixth test switch SW6, and a second terminal of the eighth test switch SW8 may be connected to the second test signal line 148 configured to supply the second test signal DC_B. The eighth test switch SW8 may be turned on during the lighting test and turned off during the link line test.

The seventh test switch SW7 and the eighth test switch SW8 may be selectively turned on during the lighting test and the link line test so that a light test signal and a link line test signal may be selectively applied.

As the lighting test and the link line test are performed, each of the first to fifth control signal lines 141 to 145 may receive control signals (TEST_GATE_R, TEST_GATE_B, TEST_GATE_G, TEST_GATE_G1, and TEST_GATE_G2) having a gate-on level or a gate-off level from the pad unit 180, and turn on or off of the first to eighth switches SW1 to SW8 according to the control signals. A gate-on level signal and a gate-off level signal may be different depending on a type (P-type or N-type) of a test switch. If the test switch may be a P-type, the gate-on level signal may be a high level signal and the gate-off level signal may be a low level signal. If the test switch is an N-type, the gate-on level signal may be a low level signal and the gate-off level signal may be a high level signal.

From the pad unit 180, the first to third test signal lines 146 to 148 may receive first to third pixel test signals as the lighting test is executed, and first to third link line test signals as the link line test is executed.

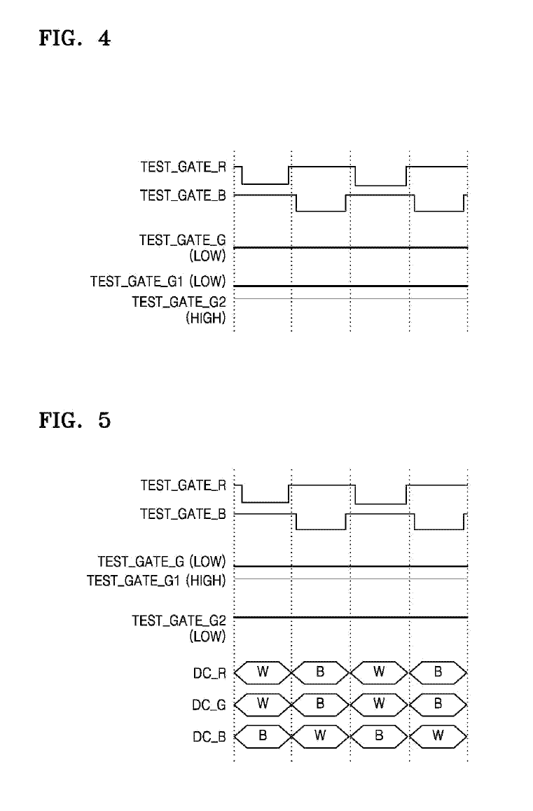

FIG. 4 is a timing diagram for describing a lighting test of the organic light-emitting display panel 100 of FIG. 3.

During the lighting test, the fourth control signal TEST_GATE_G1 having a low level may be applied to the gate of the seventh test switch SW7, and thus the seventh test switch SW7 may be turned on. The fifth control signal TEST_GATE_G2 having a high level may be applied to the gate of the eighth test switch SW8, and thus the eighth test switch SW8 may be turned off. Accordingly, the seventh test switch SW7 may be connected to the sixth test switch SW6.

The third control signal TEST_GATE_G having a low level may be applied to the respective gates of the third test switch SW3 and the sixth test switch SW6, and thus the third test switch SW3 and the sixth test switch SW6 may be turned on.

The first control signal TEST_GATE_R alternates between high level and low level every time section and may be applied to the first test switches SW1 and the fourth test switches SW4, and thus the first test switches SW1 and the fourth test switches SW4 may be alternately turned on and off.

The second control signal TEST_GATE_B alternates between high level and low level every time section and may be applied to the second test switches SW2 and the fifth test switches SW5, and thus the second test switches SW2 and the fifth test switches SW5 may be alternately turned on and off.

In this case, a first pixel test signal DC_R may be applied to the first test signal line 146, a second pixel test signal DC_B may be applied to the second test signal line 148, and a third pixel test signal DC_G may be applied to the third test signal line 147.

During a first time section, the first control signal TEST_GATE_R having a gate-on level may be applied to the first control signal line 141, and thus the first test switch SW1 and the fourth test switch SW4 may be turned on. The second control signal TEST_GATE_B having a gate-off level may be applied to the second control signal line 143, and thus the second test switch SW2 and the fifth test switch SW5 may be turned off. The third control signal TEST_GATE_G having a gate-on level may be applied to the third control signal line 142, and thus the third test switch SW3 and the sixth test switch SW6 may be turned on. The fourth control signal TEST_GATE_G1 having a gate-on level may be applied to the fourth control signal line 144, and thus the seventh test switch SW7 may be turned on. The fifth control signal TEST_GATE_G2 having a gate-off level may be applied to the fifth control signal line 145, and thus the eighth test switch SW8 may be turned off. Accordingly, the first pixel test signal DC_R may be applied to a first link line L1 connected to a data line D1 of the first column, the third pixel test signal DC_G may be applied to a second link line L2 connected to a data line D2 of the second column, the second pixel test signal DC_B may be applied to a third link line L3 connected to a data line D3 of the third column, and the third pixel test signal DC_G may be applied to a fourth link line L4 connected to a data line D4 of the fourth column.

Similarly, during a second time section, the first control signal TEST_GATE_R having a gate-off level may be applied to the first control signal line 141, and thus the first test switch SW1 and the fourth test switch SW4 may be turned off. The second control signal TEST_GATE_B having a gate-on level may be applied to the second control signal line 143, and thus the second test switch SW2 and the fifth test switch SW5 may be turned on. The third control signal TEST_GATE_G having a gate-on level may be applied to the third control signal line 142, and thus the third test switch SW3 and the sixth test switch SW6 may be turned on. The fourth control signal TEST_GATE_G1 having a gate-on level may be applied to the fourth control signal line 144, and thus the seventh test switch SW7 may be turned on. The fifth control signal TEST_GATE_G2 having a gate-off level may be applied to the fifth control signal line 145, and thus the eighth test switch SW8 may be turned off. Accordingly, the second pixel test signal DC_B may be applied to the first link line L1 connected to the data line D1 of the first column, the third pixel test signal DC_G may be applied to the second link line L2 connected to the data line D2 of the second column, the first pixel test signal DC_R may be applied to the third link line L3 connected to the data line D3 of the third column, and the third pixel test signal DC_G may be applied to the fourth link line L4 connected to the data line D4 of the fourth column.

FIG. 5 is a timing diagram for describing a link line test of the organic light-emitting display panel 100 of FIG. 3.

During the link line test, the fifth control signal TEST_GATE_G2 having a low level may be applied to the gate of the eighth test switches SW8, and thus the eighth test switches SW8 may be turned on.

The third control signal TEST_GATE_G having a low level may be applied to the respective gates of the third test switches SW3 and the sixth test switches SW6, and thus the third test switches SW3 and the sixth test switches SW6 may be turned on.

The fourth control signal TEST_GATE_G1 having a high level may be applied to the gate of the seventh test switches SW7, and thus the seventh test switches SW7 may be turned off.

The first control signal TEST_GATE_R alternates between high level and low level every time section and may be applied to the first test switches SW1 and the fourth test switches SW4, and thus the first test switches SW1 and the fourth test switches SW4 may be alternately turned on and off.

The second control signal TEST_GATE_B alternates between high level and low level every time section and may be applied to the second test switches SW2 and the fifth test switches SW5, and thus the second test switches SW2 and the fifth test switches SW5 may be alternately turned on and off.

A first link line test signal DC_R may be applied to the first test signal line 146, a second link line test signal DC_B may be applied to the second test signal line 148, and a third link line test signal DC_G may be applied to the third test signal line 147. The first link line test signal DC_R, the second link line test signal DC_B, and the third link line test signal DC_G may be first grayscale data having a white grayscale or second grayscale data having a black grayscale.

If the link lines L1 to Lm of the fanout unit 200 are disposed on the same layer, intervals between the link lines L1 to Lm may be narrow, and thus there may be a high risk of short circuits. According to an exemplary embodiment, in order to reduce the risk of short circuits between the link lines L1 to Lm, the odd number link lines (L1, L3, . . . , Lm−1) may be formed at predetermined intervals on a first conductive layer on a substrate, and the even number link lines (L2, L4, . . . , Lm) may be formed at predetermined intervals on a second conductive layer different from the first conductive layer.

The test unit 140 may apply link line test signals representing different grayscale values to adjacent link lines on the same layer to detect a short state or an open state of the adjacent link lines on the same layer.

Link line test signals representing different grayscale values may be respectively applied to the first test switches SW1 and the fourth test switches SW4, that are simultaneously connected to the odd number link lines (L1, L3, . . . , Lm−1) according to the first control signal TEST_GATE_R. Link line test signals representing different grayscale values may be respectively applied to the second test switches SW2 and the fifth test switches SW5, that are simultaneously connected to the odd number link lines (L1, L3, . . . , Lm−1) according to the second control signal TEST_GATE_B.

Link line test signals representing different grayscale values may be applied to the third test switches SW3 and the sixth test switches SW6 that are simultaneously connected to the even number link lines (L2, L4, . . . , Lm) according to the third control signal TEST_GATE_G.

For example, during a first time section, the first control signal TEST_GATE_R having a gate-on level may be applied to the first control signal line 141, and thus the first test switch SW1 and the fourth test switch SW4 may be turned on. The second control signal TEST_GATE_B having a gate-off level may be applied to the second control signal line 143, and thus the second test switch SW2 and the fifth test switch SW5 may be turned off. The third control signal TEST_GATE_G having a gate-on level may be applied to the third control signal line 142, and thus the third test switch SW3 and the sixth test switch SW6 may be turned on. The fourth control signal TEST_GATE_G1 having a gate-off level may be applied to the fourth control signal line 144, and thus the seventh test switch SW7 may be turned off. The fifth control signal TEST_GATE_G2 having a gate-on level may be applied to the fifth control signal line 145, and thus the eighth test switch SW8 may be turned on. In the present exemplary embodiment, the first link line test signal DC_R may be a white grayscale signal, the second link line test signal DC_B may be a black grayscale signal, and the third link line test signal DC_G may be a white grayscale signal. Accordingly, the white grayscale signal may be applied to the first link line L1 connected to the data line D1 of the first column, the white grayscale signal may be applied to the second link line L2 connected to the data line D2 of the second column, the black grayscale signal may be applied to the third link line L3 connected to the data line D3 of the third column, and the black grayscale signal may be applied to the fourth link line L4 connected to the data line D4 of the fourth column. A white grayscale signal may be applied to the first link line L1 and the second link line L2 that are adjacently arranged on different layers. A black grayscale signal may be applied to third link line L3 and the fourth link line L4 that are adjacently arranged on different layers. Signals representing different grayscale values, that is, the white grayscale signal and the black grayscale signal, may be respectively applied to the first link line L1 and the third link line L3 that are adjacently arranged on the same layer. Similarly, signals representing different grayscale values, that is, the white grayscale signal and the black grayscale signal, may be respectively applied to the second link line L2 and the fourth link line L4 that are adjacently arranged on the same layer. That is, the link line test may be performed by applying signals representing different grayscale values to link lines that are adjacently arranged on the same layer.

Similarly, during a second time section, the first control signal TEST_GATE_R having a gate-off level may be applied to the first control signal line 141, and the first test switch SW1 and the fourth test switch SW4 may be turned off. The second control signal TEST_GATE_B having a gate-on level may be applied to the second control signal line 143, and thus the second test switch SW2 and the fifth test switch SW5 may be turned on. The third control signal TEST_GATE_G having a gate-on level may be applied to the third control signal line 142, and thus the third test switch SW3 and the sixth test switch SW6 may be turned on. The fourth control signal TEST_GATE_G1 having a gate-off level may be applied to the fourth control signal line 144, and thus the seventh test switch SW7 may be turned off. The fifth control signal TEST_GATE_G2 having a gate-on level may be applied to the fifth control signal line 145, and thus the eighth test switch SW8 may be turned on. In the present exemplary embodiment, the first link line test signal DC_R may be a black grayscale signal, the second link line test signal DC_B may be a white grayscale signal, and third link line test signal DC_G may be a black grayscale signal. Accordingly, the white grayscale signal may be applied to the first link line L1 connected to the data line D1 of the first column, the black grayscale signal may be applied to the second link line L2 connected to the data line D2 of the second column, the black grayscale signal may be applied to the third link line L3 connected to the data line D3 of the third column, and the white grayscale signal may be applied to the fourth link line L4 connected to the data line D4 of the fourth column. Signals representing different grayscale values, that is, the white grayscale signal and the black grayscale signal, may respectively be applied to the first link line L1 and the second link line L2 that are adjacently arranged on different layers. Signals representing different grayscale values, that is, the black grayscale signal and the white grayscale signal, may respectively be applied to the third link line L3 and the fourth link line L4 that are adjacently arranged on different layers. Signals representing different grayscale values, that is, the white grayscale signal and the black grayscale signal, may respectively be applied to the first link line L1 and the third link line L3 that are adjacently arranged on the same layer. Similarly, signals representing different grayscale values, that is, the black grayscale signal and the white grayscale signal, may respectively be applied to the second link line L2 and the fourth link line L4 that are adjacently arranged on the same layer. That is, the link line test may be performed by applying signals representing different grayscale values to link lines that are adjacently arranged on the same layer.

The organic light-emitting display panel 100 according to an embodiment may include a common test circuit for selectively performing the lighting test and the link line test. Accordingly, dead space may be reduced by eliminating separate test circuits. Also, different tests may be performed by using a single common test circuit, and thus, the organic light-emitting display panel 100 may includes less signals and pads that supply signals.

Although the first to eighth switches SW1 to SW8 are both illustrated as P-type metal oxide semiconductor (PMOS) transistors according to the exemplary embodiments, the first to eighth switches SW1 to SW8 are not limited thereto. For example, the first to eighth switches SW1 to SW8 may both be an N-type metal oxide semiconductor (NMOS) transistor or different type transistors. The voltage level of a signal required to turn the transistors on or off may be configured according to the types of the transistors.

As described above, according to the one or more of the above exemplary embodiments, a composite circuit that may be used for a lighting test and a link line test may be formed in a lower space of a COG mount area. Thus, a plurality of tests may be selectively performed to detect defects of a panel, and the panel may be formed slim from the reduced dead space.

It will be understood that when an element or layer is referred to as being “on” or “connected to” another element or layer, it can be directly on or directly connected to the other element or layer, or intervening elements or layers may be present. In contrast, when an element or layer is referred to as being “directly on” or “directly connected to” another element or layer, there are no intervening elements or layers present. It will be understood that for the purposes of this disclosure, “at least one of X, Y, and Z” can be construed as X only, Y only, Z only, or any combination of two or more items X, Y, and Z (e.g., XYZ, XYY, YZ, ZZ).

What is claimed is:

1. An organic light-emitting display panel, comprising:
a pixel unit comprising a plurality of pixels configured to display different colors, wherein the plurality of pixels is respectively disposed at intersections of a plurality of scan lines and a plurality of data lines; and
a test unit configured to selectively apply, to a plurality of link lines connected to the data lines, a pixel test signal for detecting defects of the plurality of pixels and a link line test signal for detecting short and open states of the plurality of link lines.

2. The organic light-emitting display panel of claim 1, wherein the plurality of link lines comprise odd number link lines and even number link lines,
wherein the odd number link lines are disposed on a first layer and the even number link lines are disposed on a second layer, and
at least one insulating layer is disposed between the first layer and the second layer.

3. The organic light-emitting display panel of claim 1, wherein the plurality of pixels comprises:
first pixels and second pixels alternately arranged in a first column and alternately arranged in a third column; and
third pixels arranged in a second column between the first and third columns, and arranged in a fourth column adjacent to the third column,
wherein an order in which the first and second pixels are arranged in the third column is opposite to an order in which the first and second pixels are arranged in the first column.

4. The organic light-emitting display panel of claim 3, wherein the test unit comprises a plurality of test switches, wherein each of the plurality of test switches comprises:
a gate connected to one of a plurality of control signal lines each configured to supply a test control signal,
a first terminal connected to one of the plurality of data lines via one of the plurality of link lines, and
a second terminal connected to one of a plurality of test signal lines configured to supply one of pixel test signals and link line test signals.

5. The organic light-emitting display panel of claim 4, wherein the plurality of test switches comprises:
a first test switch comprising a gate connected to a first control signal line, a first terminal connected to a data line of the first column, and a second terminal connected to a first test signal line;
a second test switch comprising a gate connected to a second control signal line, a first terminal connected to the data line of the first column, and a second terminal connected to a second test signal line;
a third test switch comprising a gate connected to a third control signal line, a first terminal connected to a data line of the second column, and a second terminal connected to a third test signal line;
a fourth test switch comprising a gate connected to the first control signal line, a first terminal connected to a data line of the third column, and a second terminal connected to the second test signal line;
a fifth test switch comprising a gate connected to the second control signal line, a first terminal connected to the data line of the third column, and a second terminal connected to the first test signal line;
a sixth test switch comprising a gate connected to the third control signal line, and a first terminal connected to a data line of the fourth column;
a seventh test switch comprising a gate connected to a fourth control signal line, a first terminal connected to a second terminal of the sixth test switch, and a second terminal connected to the third test signal line; and
an eighth test switch comprising a gate connected to a fifth control signal line, a first terminal connected to the second terminal of the sixth test switch, and a second terminal connected to the second test signal line.

6. The organic light-emitting display panel of claim 5, wherein the test unit is configured to alternately apply the gate-on level signal to the first and second control signal lines in response to a gate-on level signal applied to the third and fourth control signal lines and a gate-off level signal applied to the fifth control signal line.

7. The organic light-emitting display panel of claim 6, wherein a first pixel test signal is applied to the first test signal line,
a second pixel test signal is applied to the second test signal line, and
a third pixel test signal is applied to the third test signal line.

8. The organic light-emitting display panel of claim 5, wherein the test unit is configured to alternately apply the gate-on level signal to the first and second control signal lines in response to a gate-on level signal applied to the third and fifth control signal lines and a gate-off level signal applied to the fourth control signal line.

9. The organic light-emitting display panel of claim 8, wherein a first link line test signal is applied to the first test signal line,
a second link line test signal is applied to the second test signal line, and
a third link line test signal is applied to the third test signal line.

10. The organic light-emitting display panel of claim 9, wherein a first grayscale signal is applied to the first and third test signal lines as each of the first and third link line test signals, and a second grayscale signal is applied to the second test signal line as the second link line test signal in response to the gate-on signal applied to the first control signal line, and
wherein the second grayscale signal is applied to the first and third test signal lines as each of the first and third link line test signals and the first grayscale signal is applied to the second test signal line as the second link line test signal in response to the gate-on level signal applied to the second control signal line.

11. The organic light-emitting display panel of claim 8, wherein the pixel test signal and the link line test signal are direct current (DC) signals.

12. The organic light-emitting display panel of claim 1, further comprising a plurality of pads that respectively connect the plurality of data lines to the plurality of link lines.

13. A method of testing an organic light-emitting display panel, comprising:
applying a pixel test signal, for detecting a lighting defect of a plurality of pixels, to a plurality of link lines respectively connected to a plurality of data lines; and
applying a link line test signal, for detecting short and open states of the plurality of link lines, to the plurality of link lines.

14. The method of claim 13, wherein the plurality of link lines comprises odd number link lines and even number link lines,
wherein the odd number link lines are disposed on a first layer and the even number link lines are disposed on a second layer, and
at least one insulating layer disposed between the first layer and the second layer.

15. The method of claim 13, wherein the plurality of pixels comprise:
first pixels and second pixels alternately arranged in a first column and alternately arranged in a third column; and
third pixels arranged in a second column between the first and third columns and arranged in a fourth column adjacent to the third column,
wherein an order in which the first pixels and the second pixels are arranged in the third column is opposite to an order in which the first pixels and the second pixels are arranged in the first column.

16. The method of claim 15, wherein the organic light-emitting display panel comprises:
a first test switch comprising a gate connected to a first control signal line, a first terminal connected to a data line of the first column, and a second terminal connected to a first test signal line;
a second test switch comprising a gate connected to a second control signal line, a first terminal connected to the data line of the first column, and a second terminal connected to a second test signal line;
a third test switch comprising a gate connected to a third control signal line, a first terminal connected to a data line of the second column, and a second terminal connected to a third test signal line;
a fourth test switch comprising a gate connected to the first control signal line, a first terminal connected to a data line of the third column, and a second terminal connected to the second test signal line;
a fifth test switch comprising a gate connected to the second control signal line, a first terminal connected to the data line of the third column, and a second terminal connected to the first test signal line;
a sixth test switch comprising a gate connected to the third control signal line, and a first terminal connected to a data line of the fourth column;
a seventh test switch comprising a gate connected to a fourth control signal line, a first terminal connected to a second terminal of the sixth test switch, and a second terminal connected to the third test signal line; and
an eighth test switch comprising a gate connected to a fifth control signal line, a first terminal connected to the second terminal of the sixth test switch, and a second terminal connected to the second test signal line.

17. The method of claim 16, wherein the applying of the pixel test signal comprising:
alternately applying the gate-on level signal to the first and second control signal lines in response to in response to a gate-on level signal applied to the third and fourth control signal lines and a gate-off level signal applied to the fifth control signal line; and
respectively applying first to third pixel test signal to the first to third test signal lines.

18. The method of claim 16, wherein the applying of the link line test signal comprising:
alternately applying the gate-on level signal to the first and second control signal lines in response to a gate-on level signal applied to the third and fifth control signal lines and a gate-off level signal applied to the fourth control signal line; and
respectively applying first to third link line test signal to the first to third test signal lines.

19. The method of claim 18, wherein a first grayscale signal is applied to the first and third test signal lines as each of the first and third link line test signals, and a second grayscale signal is applied to the second test signal line as the second link line test signal in response to the gate-on level signal applied to the first control signal line, and
wherein the second grayscale signal is applied to the first and third test signal lines as each of the first and third link line test signal and the first grayscale is applied to the second test signal line as the second link line test signal.
